(19) United States
(12) Patent Application Publication
(10) Pub. No.: US 2023/0299018 A1
(43) Pub. Date: Sep. 21, 2023

(54) PACKAGE SUBSTRATE AND COMMUNICATION DEVICE

(71) Applicant: HUAWEI TECHNOLOGIES CO., LTD., Shenzhen (CN)

(72) Inventors: Chen KANG, Shanghai (CN); Chao SHEN, Shanghai (CN); Xiaojing LIAO, Shanghai (CN); Junhe WANG, Shanghai (CN)

(21) Appl. No.: 18/324,329

(22) Filed: May 26, 2023

Related U.S. Application Data
(63) Continuation of application No. PCT/CN2021/094104, filed on May 17, 2021.

(30) Foreign Application Priority Data
Nov. 30, 2020 (CN) 202011377915.6

(51) Int. Cl. H01L 23/00; H01L 23/552; H01L 23/31; H05K 1/18; H01L 23/498

(52) U.S. Cl. CPC H01L 23/564; H01L 23/552; H01L 23/31; H05K 1/185; H01L 23/49822; H05K 2201/0206

(57) ABSTRACT

This application provides a package substrate and a communication device. The package substrate includes a package body, a first circuit layer, a second circuit layer, an electronic component, and a moisture-proof structure. The package body includes a top surface and a bottom surface that are oppositely disposed, the first circuit layer is disposed on the top surface of the package body, and the second circuit layer is disposed on the bottom surface of the package body. The electronic component is packaged inside the package body. The moisture-proof structure is disposed on the package body and is connected between the first circuit layer and the second circuit layer, and the moisture-proof structure surrounds the electronic component. According to technical solutions of this application, external water vapor can be prevented from entering the package substrate from a peripheral side of the package substrate, to effectively prevent moisture absorption.

### CROSS-REFERENCE TO RELATED APPLICATIONS

This application is a continuation of International Application No. PCT/CN2021/094104, filed on May 17, 2021, which claims priority to Chinese Patent Application No. 202011377915.6, filed on Nov. 30, 2020. The disclosures of the aforementioned applications are hereby incorporated by reference in their entireties.

### TECHNICAL FIELD

This application relates to the field of packaging technologies, and in particular, to a package substrate and a communication device.

### BACKGROUND

With development of electronic products towards miniaturization, portability, and multifunction, a chip-embedded package substrate has become a research hotspot in the field of electronic component packaging technologies. After an existing chip is embedded in a substrate, external water vapor easily enters the package substrate from a peripheral side of the package substrate; and consequently the package substrate is faulty due to moisture absorption.

### SUMMARY

An embodiment of this application provides a package substrate and a communication device, to prevent external water vapor from entering the package substrate from a peripheral side of the package substrate, and effectively prevent a failure of the package substrate due to moisture absorption.

According to a first aspect, this application provides a package substrate, including:

a package body, where the package body includes a top surface and a bottom surface that are oppositely disposed;

a first circuit layer and a second circuit layer, where the first circuit layer is disposed on the top surface of the package body, and the second circuit layer is disposed on the bottom surface of the package body;

an electronic component, where the electronic component is packaged inside the package body; and

a moisture-proof structure, where the moisture-proof structure is disposed on the package body and is connected between the first circuit layer and the second circuit layer, and the moisture-proof structure surrounds the electronic component.

It may be understood that the package body made of a package material has specific moisture absorption performance, and may absorb moisture in an external environment. However, the electronic component is in a structure packaged in the package body, and at a joint between a pin of the electronic component and the package body, a small gap is easily generated. After moisture is absorbed, an electric-leakage path is easily formed at these small gaps, and consequently, the package substrate is faulty when powered on for use. Therefore, the moisture-proof structure is disposed, and the moisture-proof structure can be disposed around a periphery of the electronic component in a surrounding structure, so that the electronic component can be within a protection range of the moisture-proof structure. In other words, the electronic component is located inside the moisture-proof structure, and can have good moisture-proof performance due to protection of the moisture-proof structure. This helps better ensure electrical performance of the electronic component. In addition, the surrounding structure may maximize a feature of blocking external moisture in various directions, and maximizes a role of moisture-proof protection. In addition, because the moisture-proof structure is further connected between the first circuit layer and the second circuit layer, a height of the moisture-proof structure can completely occupy a height interval between the first circuit layer and the second circuit layer, that is, the height of the moisture-proof structure can completely adapt to the height interval of the package body, to implement a tight blocking function, and minimize a possibility that the external moisture may pass through the moisture-proof structure and further penetrate into the package body.

In other words, the moisture-proof structure is disposed, so that the inside of the moisture-proof structure is defined as an area in which moisture cannot enter, and even if the moisture converges from the outside of the moisture-proof structure to a position of the moisture-proof structure, the moisture cannot pass through the moisture-proof structure to enter the defined area protected by the moisture-proof structure due to a moisture-proof feature of the moisture-proof structure. This can effectively prevent the external moisture from entering the package substrate from a side edge of the package substrate, and prevent a failure of the package substrate due to moisture absorption, and the package substrate has good moisture-proof performance. In addition, the package substrate can have a good environment adaptability as a whole, and can cope with complex and changeable environment changes, so that even in a damp and hot external environment, the package substrate can have good moisture-proof performance, to effectively isolate external moisture, dust, and the like, so as to have high reliability and high practicability.

In a possible implementation, the moisture-proof structure is a continuously-extending closed ring structure.

In this way, the moisture-proof structure can form a continuous surrounding architecture, and the continuous surrounding architecture can maximize sealing performance of the moisture-proof structure, so that external moisture is hermetically blocked outside the continuous surrounding architecture. This helps ensure overall electrical performance of the package substrate.

Alternatively, the moisture-proof structure includes a plurality of moisture-proof substructures, the plurality of moisture-proof substructures are distributed in a staggered manner, and two adjacent moisture-proof substructures at least partially overlap.

For example, the plurality of moisture-proof substructures may be arranged in a four-side staggered form. It should be understood that, that two adjacent moisture-proof substructures located on a same side at least partially overlap may be understood as that, on a reference surface parallel to the two adjacent moisture-proof substructures, orthographic projection that is of one moisture-proof substructure and that is on the reference surface at least partially falls within a range of orthographic projection that is of the other moisture-proof substructure and that is on the reference surface. That two adjacent moisture-proof substructures at least partially overlap may not only mean that the two adjacent moisture-proof substructures located on a same side at least partially overlap, but also may mean that two adjacent moisture-proof substructures located at a corner at least partially overlap.

In this way, the plurality of moisture-proof substructures can be in a discontinuous surrounding structure, and two adjacent moisture-proof substructures do not have a direct connection relationship, and can be in an arrangement form in which positions are staggered. In addition, the two adjacent moisture-proof substructures at least partially overlap, so that an outer contour surrounded by the plurality of moisture-proof substructures is generally in an annular surrounding form, that is, the plurality of moisture-proof substructures can be in a staggered blocking form. This helps minimize a possibility that the external moisture penetrates to cause a failure of the package substrate due to moisture absorption.

It should be noted that an arrangement form of the plurality of moisture-proof substructures is not limited to the foregoing described possibilities. The arrangement form may alternatively be that one side is continuous and three sides are staggered, or may be that two sides are continuous and two sides are staggered, or may be that three sides are continuous and one side is staggered. Staggered and continuous arrangement and combination forms are not listed herein. However, it should be understood that this application is not limited thereto.

In a possible implementation, the moisture-proof structure is embedded in the package body. It should be understood that, that the moisture-proof structure is embedded in the package body may be understood as that the moisture-proof structure is completely disposed inside the package body. That is, the electronic component is inside the moisture-proof structure, and a circle of the package material of the package body is still disposed outside the moisture-proof structure. That is, the moisture-proof structure is still at a specific distance from the peripheral side surface of the package body.

In this way, the moisture-proof structure is completely disposed inside the package body, so that even if moisture aggregates from the package body disposed outside the moisture-proof structure to the position of the moisture-proof structure, the moisture cannot pass through the moisture-proof structure to enter the small gap between the package body and the pin of the electronic component due to the moisture-proof feature of the moisture-proof structure. This can effectively prevent a failure of the package substrate due to moisture absorption, and the package substrate has good moisture-proof performance.

Alternatively, at least a part of the moisture-proof structure is exposed on a side portion of the package body.

Therefore, the moisture-proof structure can hermetically block moisture of an external environment outside the package body, and further prevent the moisture of the external environment from entering the package body. This helps ensure electrical performance of the package substrate.

In a possible implementation, the package body includes a frame and a package layer, the frame is provided with a cavity, the electronic component is accommodated in the cavity, the frame further includes a first surface and a second surface that are oppositely disposed, the package layer is filled in the cavity, to wrap the electronic component and cover the first surface and the second surface, and surfaces of the package layer that are away from the frame form the top surface and the bottom surface.

The moisture-proof structure includes a frame baffle wall and a package baffle wall, the frame baffle wall is disposed on the frame, and the package baffle wall is disposed on the package layer.

The package baffle wall is connected between the frame baffle wall and the first circuit layer and connected between the frame baffle wall and the second circuit layer, and orthographic projection that is of the package baffle wall and that is on the first surface at least partially falls within a range of orthographic projection that is of the frame baffle wall and that is on the first surface.

Alternatively, the package baffle wall is connected between the first surface and the first circuit layer and connected between the second surface and the second circuit layer, and the package baffle wall and the frame baffle are disposed in a staggered manner.

Alternatively, the package baffle wall is connected between the first surface and the first circuit layer and connected between the second surface and the second circuit layer, and the package baffle wall is adjacent to the frame baffle wall.

It may be understood that the frame baffle wall and the package baffle wall jointly form the moisture-proof structure. Because the moisture-proof structure may have only a moisture-proof function but does not have a function of electrically connecting the first circuit layer and the second circuit layer, specific positions of the frame baffle wall and the package baffle wall may be diversified. This disposition can further increase a degree of freedom of manufacturing the moisture-proof structure, and help reduce a difficulty of manufacturing the package substrate.

Therefore, on one hand, it can be ensured that the moisture-proof structure can be hermetically disposed between the first circuit layer and the second circuit layer, to minimize a possibility of a problem that moisture outside the package substrate penetrates from a loose connection position because the moisture-proof structure is not hermetically connected to the first circuit layer and the second circuit layer, resulting in a failure of the package substrate due to moisture absorption. On the other hand, because the moisture-proof structure is disposed on each side of the side portion of the package body, moisture from various directions can be effectively blocked, to further improve moisture-proof performance of the package substrate.

In a possible implementation, the electronic component is a chip, the package substrate further includes a signal shielding structure disposed on the frame, and the signal shielding structure is located between the package baffle wall and the cavity and surrounds the cavity.

It may be understood that, the signal shielding structure can be disposed, to avoid signal interference, ensure precision of signal transmission of the chip, and improve stability of the chip during working, so as to minimize a possibility of an exception of the package substrate during working, and fully ensure stability of the package substrate during working.

In a possible implementation, the signal shielding structure is a continuously-extending closed ring structure.

In this way, the signal shielding structure can be disposed around the periphery of the cavity in which the chip is disposed, to form a continuous surrounding architecture. The continuous surrounding architecture can maximize sealing performance of the signal shielding structure, and play a good role of shielding signal interference. This helps ensure overall electrical performance of the package substrate.

Alternatively, the signal shielding structure includes a shielding baffle wall and a shielding top cover, the shielding baffle wall is disposed around a periphery of the cavity, and at least a part of the shielding top cover is located in the cavity and is connected to one end of the shielding baffle wall.

For example, the plurality of signal shielding substructures may be in a four-side staggered form. It should be understood that, that two adjacent signal shielding substructures located on a same side at least partially overlap may be understood as that, on a reference surface parallel to the two adjacent signal shielding substructures, orthographic projection that is of one signal shielding substructure and that is on the reference surface at least partially falls within a range of orthographic projection that is of the other signal shielding substructure and that is on the reference surface. That two adjacent signal shielding substructures at least partially overlap may not only mean that the two adjacent signal shielding substructures located on a same side at least partially overlap, but also may mean that two adjacent signal shielding substructures located at a corner at least partially overlap.

In this way, the plurality of signal shielding substructures can be disposed around the periphery of the cavity in which the chip is disposed, to form the discontinuous surrounding structure, and two adjacent signal shielding substructures do not have a direct connection relationship, and can be in an arrangement form in which positions are staggered. In addition, the two adjacent signal shielding substructures at least partially overlap, so that an outer contour surrounded by the plurality of signal shielding substructures is generally in an annular surrounding form, that is, the plurality of signal shielding substructures can be in a staggered blocking form. This helps minimize a possibility that external moisture penetrates to cause a failure of the package substrate due to moisture absorption.

It should be noted that an arrangement form of the plurality of signal shielding substructures is not limited to the foregoing described possibilities. The arrangement form may alternatively be that one side is continuous and three sides are staggered, or may be that two sides are continuous and two sides are staggered, or may be that three sides are continuous and one side is staggered. Staggered and continuous arrangement and combination forms are not listed herein. However, it should be understood that this application is not limited thereto.

In a possible implementation, the package substrate further includes a conductive connecting block disposed on the frame, and the frame further includes a peripheral side surface connecting the first surface and the second surface.

The conductive connecting block is located outside the cavity, and is electrically connected between the first circuit layer and the second circuit layer, and a distance between the conductive connecting block and the peripheral side surface of the frame is greater than a distance between the moisture-proof structure and the frame.

It may be understood that, the conductive connecting block can form an electrical connection relationship between the first circuit layer and the second circuit layer, so that the electronic component can implement double-sided interconnection by using the conductive connecting block.

In this way, the conductive connecting block is disposed, so that double-sided interconnection of the electronic component can be implemented. This helps shorten a cabling distance and maximize a short-distance transmission path, can effectively implement higher power with a smaller area or volume, and can improve an overall power density, arrangement density, and integration degree of the package substrate.

In a possible implementation, the package body further includes a metal layer, the metal layer is embedded in a middle position in a thickness direction of the frame, and the metal layer extends along a direction parallel to the package substrate.

In this way, one metal layer is added at the middle position in the thickness direction of the frame. Due to a structure feature of the metal layer, the frame has good heat dissipation performance as a whole, to significantly improve overall heat dissipation performance and stability of the package substrate, and mechanical strength of the frame may be increased, so that the frame does not easily deform due to an external force, to improve the mechanical strength of the package substrate.

In a possible implementation, the metal layer intersects with the conductive connecting block, and the metal layer is electrically connected to the conductive connecting block.

It may be understood that the metal layer can be arranged as a circuit layer and provide specific cabling design. In addition, because the metal layer is connected to the conductive connecting block that can implement a double-sided interconnection function, the metal layer may be manufactured as an interconnection circuit according to an actual design requirement, and a signal shield layer between an upper surface and a lower surface (the first surface and the second surface) is formed. In this way, the metal layer can improve the heat dissipation performance, improve the mechanical strength, and provide the cabling design, and has diversified performance, high flexibility, and a wide application scope.

It should be noted that, when the metal layer is disposed as a circuit layer, the metal layer may be discontinuously-extending layer structure design, namely, discontinuous layer structure design. The discontinuous structure design can reserve a specific loop for double-sided interconnection, to ensure reliability of double-sided interconnection.

In a possible implementation, the package substrate further includes a first solder mask layer and a second solder mask layer.

The first solder mask layer is disposed on a surface that is of the first circuit layer and that is away from the package body, and covers a part of the top surface that is of the package body and that is not covered by the first circuit layer, the first solder mask layer is provided with a first opening, and the first opening exposes a part of the first circuit layer, so that the exposed part of the first circuit layer forms a first pad of the package substrate.

The second solder mask layer is disposed on a surface that is of the second circuit layer and that is away from the package body, and covers a part of the bottom surface that is of the package body and that is not covered by the second circuit layer, the second solder mask layer is provided with a second opening, and the second opening exposes a part of the second circuit layer, so that the exposed part of the second circuit layer forms a second pad of the package substrate.

The first circuit layer and the second circuit layer are disposed, so that the first circuit layer can shield a part of the top surface of the package body, and the second circuit layer can shield a part of the bottom surface of the package body, to block the external moisture from entering the package body. In addition, both sides (the top surface and the bottom surface) of the package body each have a circuit layer having an electrical connection function. This can provide a good foundation for double-sided interconnection of the electronic component packaged in the package body, and facilitate implementation of a shortest interconnection path and a thin package of the package substrate in a limited space layout, and the package substrate has high practicability and high reliability.

The first solder mask layer and the second solder mask layer are disposed, the first opening is provided on the first solder mask layer, and the second opening is provided on the second solder mask layer, so that a circuit and a substrate that need to be soldered in the package substrate can be exposed, to form the first pad and the second pad, and a circuit and a substrate that do not need to be soldered in the package substrate can be shielded due to a solder mask function of the first solder mask layer and the second solder mask layer. On one hand, solder waste can be avoided, and an electrical short circuit problem caused by solder bridging in a soldering process can be avoided. This facilitates long-term protection of a formed circuit pattern. On the other hand, the first solder mask layer and the second solder mask layer have good insulation performance, so that problems such as insulation deterioration and corrosion caused by external environmental factors such as dust and water vapor can be prevented, and a high density of the circuit can be implemented.

Based on the foregoing descriptions, it should be understood that the top surface of the package body may be covered by the first circuit layer and the first solder mask layer together, to prevent the external moisture. The bottom surface of the package body may also be covered by the second circuit layer and the second solder mask layer together, to prevent the external moisture. In this way, both the top surface and the bottom surface of the package substrate can have good moisture-proof performance because the top surface and the bottom surface can effectively block the external moisture.

According to a second aspect, this application further provides a communication device. The communication device includes a circuit board and the foregoing package substrate, and the package substrate is disposed on the circuit board.

### BRIEF DESCRIPTION OF DRAWINGS

FIG. 1 is a simple schematic diagram of a communication device according to an embodiment of this application;

FIG. 2 is a schematic diagram of a first profile of a package substrate according to an embodiment of this application;

FIG. 3 is a schematic diagram of a second profile of a package substrate according to an embodiment of this application;

FIG. 4 is a schematic diagram of a third profile of a package substrate according to an embodiment of this application;

FIG. 5 is a schematic diagram of a fourth profile of a package substrate according to an embodiment of this application;

FIG. 6 is a schematic diagram of a fifth profile of a package substrate according to an embodiment of this application;

FIG. 7 is a schematic diagram of a sixth profile of a package substrate according to an embodiment of this application;

FIG. 8 is a schematic diagram of a profile of a moisture-proof structure of a package substrate according to an embodiment of this application;

FIG. 9 is a schematic diagram of another profile of a moisture-proof structure of a package substrate according to an embodiment of this application;

FIG. 10 is a schematic diagram of still another profile of a moisture-proof structure of a package substrate according to an embodiment of this application;

FIG. 11 is a schematic diagram of yet another profile of a moisture-proof structure of a package substrate according to an embodiment of this application;

FIG. 12 is a schematic diagram of a fifth profile of a moisture-proof structure of a package substrate according to an embodiment of this application;

FIG. 13 is a schematic diagram of a seventh profile of a package substrate according to an embodiment of this application;

FIG. 14 is a schematic diagram of an eighth profile of a package substrate according to an embodiment of this application;

FIG. 15 is a schematic diagram of a profile of a signal shielding structure of a package substrate according to an embodiment of this application; and

FIG. 16 is a schematic diagram of another profile of a signal shielding structure of a package substrate according to an embodiment of this application.

### DESCRIPTION OF EMBODIMENTS

The following clearly describes specific implementations of this application with reference to the accompanying drawings.

An embodiment of this application provides a communication device 200. The communication device 200 may be, but is not limited to, a device such as a power supply module, a communication signal transmission base station, or an outdoor network switch device.

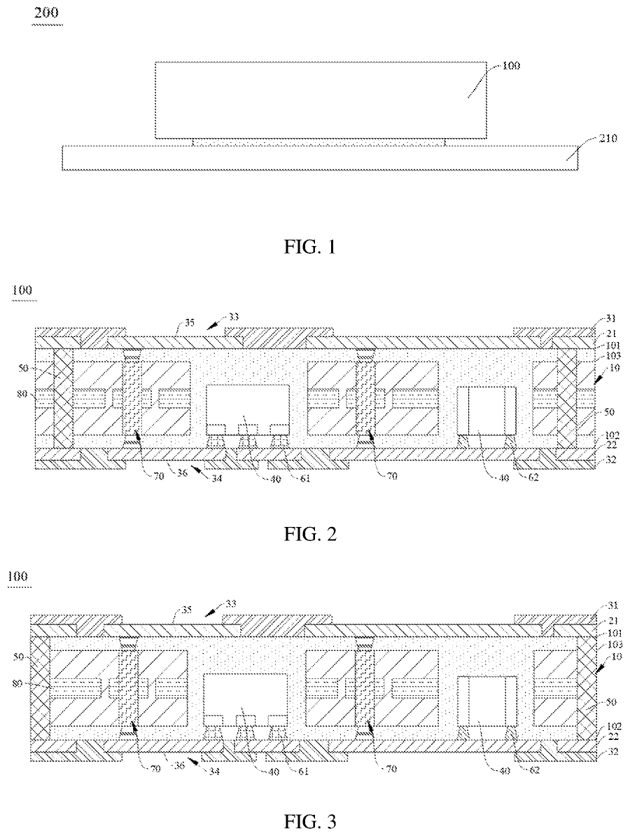

As shown in FIG. 1, the communication device 200 includes a circuit board 210 and a package substrate 100. The circuit board 210 may be understood as a carrier of the package substrate 100. The circuit board 210 can carry the package substrate 100 and be assembled with the package substrate 100, to implement electrical interconnection to the package substrate 100. The package substrate 100 may be understood as a carrier for packaging a semiconductor chip, and may provide functions such as electrical connection, protection, support, heat dissipation, and assembly to electronic components such as a chip and a resistor-capacitor component.

It should be noted that FIG. 1 is merely intended to schematically describe a connection relationship between the circuit board 210 and the package substrate 100, and is not intended to specifically limit connection positions, specific structures, and quantities of devices. A structure shown in this embodiment of this application does not constitute a specific limitation on the communication device 200. In some other embodiments of this application, the communication device 200 may include more or fewer components than those shown in the figure, or combine some components, or split some components, or have different component arrangements. The components shown in the figure may be implemented through hardware, software, or a combination of software and hardware.

In this embodiment of this application, the package substrate 100 is specifically described by using an embedded substrate as an example. It may be understood that, the embedded substrate may be understood as a packaging structure in which a chip is mounted inside the substrate, then the chip is packaged on both sides by using a package material, and then double-side interconnection is implemented by using a related process.

It may be understood that there may be a small gap between the package material and a pin of an electronic component such as a chip or a resistor-capacitor component packaged in the package material. In addition, the package material has specific moisture absorbing performance (this means that the package material has a capability of absorbing external water vapor/moisture). Therefore, when external moisture enters the package substrate 100, an electric-leakage path is easily formed at the small gap, and the electric-leakage path causes the package substrate 100 to fail when the package substrate 100 is powered on for use. However, for the entire package substrate 100, the external moisture is difficult to enter the package substrate 100 from an upper surface and a lower surface of the package substrate 100, and is more likely to enter the package substrate 100 from a side surface of the package substrate 100. That is, moisture-proof performance of the side surface of the package substrate 100 is poorer. The upper surface and the lower surface of the package substrate 100 may be understood as outer surfaces of the package substrate 100 that are parallel to a plane when the package substrate 100 is placed on the plane. The side surface of the package substrate 100 may be understood as an outer surface that is of the package substrate 100 and that is perpendicular to a reference surface when the package substrate 100 is placed on the reference surface. Based on the foregoing descriptions, corresponding structure design needs to be performed on the package substrate 100, to ensure that the entire package substrate 100 can have better moisture-proof performance.

In this way, the package substrate 100 provided in this embodiment of this application can prevent the external moisture from entering the package substrate 100 from a peripheral side of the package substrate 100, to effectively prevent a failure of the package substrate 100 due to moisture absorption, and ensure high reliability and high stability of a circuit system of the package substrate 100 in a normal working process. Details are further described below.

As shown in FIG. 2 to FIG. 7, the package substrate 100 includes a package body 10, a first circuit layer 21, a first solder mask layer 31, a first connection column 61, a second circuit layer 22, a second solder mask layer 32, a second connection column 62, an electronic component 40, a moisture-proof structure 50, a conductive connecting block 70, and a metal layer 80.

The package body 10 includes a top surface 101, a bottom surface 102, and a peripheral side surface 103 connected between the top surface 101 and the bottom surface 102. The top surface 101, the bottom surface 102, and the peripheral side surface 103 of the package body 10 are connected, to jointly form an appearance structure of the package body 10. It may be understood that, the package body 10 is placed on a reference surface, the top surface 101 of the package body 10 is a surface away from the reference surface, the bottom surface 102 of the package body 10 is a surface attached to the reference surface, and the peripheral side surface 103 of the package body 10 is a surface perpendicular to the reference surface.

The top surface 101, the bottom surface 102, and the peripheral side surface 103 of the package body 10 are the appearance structure of the package body 10 that may be exposed outside. Therefore, to prevent external moisture from entering the package body 10 from respective positions of the top surface 101, the bottom surface 102, and the peripheral side surface 103, and affecting electrical performance of the inside of the package body 10, corresponding structure design is required, to block moisture that may enter the package body 10 from the top surface 101, the bottom surface 102, and the peripheral side surface 103 of the package body 10, and implement good moisture-proof performance of the package body 10.

The first circuit layer 21 is disposed on the top surface 101 of the package body 10, and the second circuit layer 22 is disposed on the bottom surface 102 of the package body 10. It may be understood that pattern design of the first circuit layer 21 may be set according to a requirement of the electronic component 40 packaged by the package body 10, and pattern design of the second circuit layer 22 may also be set according to the requirement of the electronic component 40 packaged by the package body 10. In addition, there may be a difference between the pattern design of the first circuit layer 21 and the pattern design of the second circuit layer 22. In other words, the pattern design of the first circuit layer 21 and the pattern design of the second circuit layer 22 may be different. This is not strictly limited in this embodiment of this application. For example, materials of the first circuit layer 21 and the second circuit layer 22 may be copper.

The first circuit layer 21 and the second circuit layer 22 are disposed, so that the first circuit layer 21 can shield a part of the top surface 101 of the package body 10, and the second circuit layer 22 can shield a part of the bottom surface 102 of the package body 10, to block the external moisture from entering the package body 10. In addition, both sides (the top surface 101 and the bottom surface 102) of the package body 10 each have a circuit layer having an electrical connection function. This can provide a good foundation for double-side interconnection of the electronic component 40 packaged in the package body 10, and facilitate implementation of a shortest interconnection path and a thin package of the package substrate 100 in a limited space layout, so that the package substrate 100 has high practicability and high reliability.

The first solder mask layer 31 is disposed on a surface that is of the first circuit layer 21 and that is away from the package body 10, and covers a part of the top surface 101 that is of the package body 10 and that is not covered by the first circuit layer 21. The first solder mask layer 31 is provided with a first opening 33, and the first opening 33 exposes a part of the first circuit layer 21, so that the exposed part of the first circuit layer 21 forms a first pad 35 of the package substrate 100.

The first solder mask layer 31 is disposed, and the first opening 33 is provided on the first solder mask layer 31, so that a circuit and a substrate that need to be soldered in the package substrate 100 can be exposed, to form the first pad 35, and a circuit and a substrate that do not need to be soldered in the package substrate 100 can be shielded due to a solder mask function of the first solder mask layer 31. On one hand, solder waste can be avoided, and an electrical short circuit problem caused by solder bridging in a soldering process can be avoided. This facilitates long-time protection of a formed circuit pattern. On the other hand, the first solder mask layer 31 has good insulation performance, so that problems such as insulation deterioration and corrosion caused by external environmental factors such as dust and water vapor can be prevented, and high density of the circuit can be implemented.

It should be noted that a quantity of first openings 33, and a shape and a size of the first opening 33 may be designed based on an actual soldering status of the package substrate 100. The quantity may be one, two, or more, and the shape may be a rectangle, a circle, a polygon, or the like. This is not strictly limited in this embodiment of this application. For example, when there are a plurality of first openings 33, there are also a plurality of formed first pads 35; and sizes of the plurality of first pads 35 may be different, and shapes of the plurality of first pads 35 may be one or a combination of a rectangle, a circle, or a polygon.

The second solder mask layer 32 is disposed on a surface that is of the second circuit layer 22 and that is away from the package body 10, and covers a part of the top surface 101 that is of the package body 10 and that is not covered by the second circuit layer 22. The second solder mask layer 32 is provided with a second opening 34, and the second opening 34 exposes a part of the second circuit layer 22, so that the exposed part of the second circuit layer 22 forms a second pad 36 of the package substrate 100.

The second solder mask layer 32 is disposed, and the second opening 34 is provided on the second solder mask layer 32, so that a circuit and a substrate that need to be soldered in the package substrate 100 can be exposed, to form the second pad 36, and a circuit and a substrate that do not need to be soldered in the package substrate 100 can be shielded due to a solder mask function of the second solder mask layer 32. On one hand, solder waste can be avoided, and an electrical short circuit problem caused by solder bridging in a soldering process can be avoided. This facilitates long-time protection of a formed circuit pattern. On the other hand, the second solder mask layer 32 has good insulation performance, so that problems such as insulation deterioration and corrosion caused by external environmental factors such as dust and water vapor can be prevented, and high density of the circuit can be implemented.

It should be noted that a quantity of second openings 34, and a shape and a size of the second opening 34 may be designed based on the actual soldering status of the package substrate 100. The quantity may be one, two, or more, and the shape may be a rectangle, a circle, a polygon, or the like. This is not strictly limited in this embodiment of this application. For example, when there are a plurality of second openings 34, there are also a plurality of formed second pads 36; and sizes of the plurality of second pads 36 may be different, and shapes of the plurality of second pads 36 may be one or a combination of a rectangle, a circle, or a polygon.

Based on the foregoing descriptions, it should be understood that the top surface 101 of the package body 10 may be covered by the first circuit layer 21 and the first solder mask layer 31 together, to prevent the external moisture. The bottom surface 102 of the package body 10 may also be covered by the second circuit layer 22 and the second solder mask layer 32 together, to prevent the external moisture. In this way, both the top surface 101 and the bottom surface 102 of the package substrate 100 can have good moisture-proof performance because the top surface 101 and the bottom surface 102 can effectively block the external moisture.

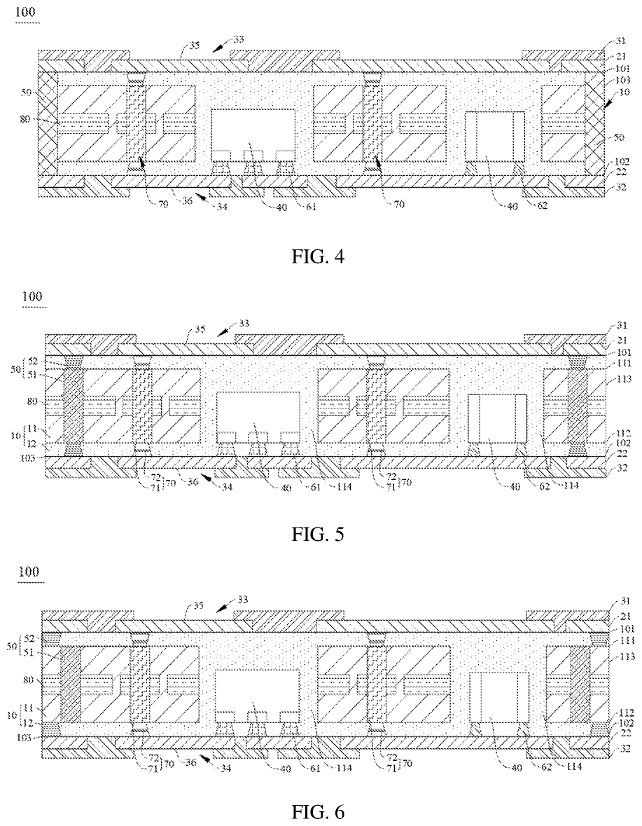

As shown in FIG. 2, FIG. 3, and FIG. 4, the electronic component 40 is packaged inside the package body 10, the moisture-proof structure 50 is disposed inside the package body 10 and is connected between the first circuit layer 21 and the second circuit layer 22, and the moisture-proof structure 50 surrounds the electronic component 40. That is, a distance between the moisture-proof structure 50 and the peripheral side surface 103 of the package body 10 is less than a distance between the electronic component 40 and the peripheral side surface 103 of the package body 10. The moisture-proof structure 50 can be in a surrounding structure that surrounds the electronic component 40 and is disposed on the package body 10, one end of the moisture-proof structure 50 is connected to the first circuit layer 21, and the other end of the moisture-proof structure 50 is connected to the second circuit layer 22.

For example, the package body 10 may be made of a resin material having specific moisture absorption performance, and the moisture-proof structure 50 may be made of a copper material.

It may be understood that the package body 10 made of the package material has specific moisture absorption performance, and may absorb moisture in an external environment. However, the electronic component 40 is a structure packaged in the package body 10, and at a joint between a pin of the electronic component 40 and the package body 10, a small gap is easily generated. After moisture is absorbed, an electric-leakage path is easily formed at these small gaps, and consequently, the package substrate 100 is faulty when the package substrate 100 is powered on for use. Therefore, the moisture-proof structure 50 is disposed, and the moisture-proof structure 50 can be disposed around a periphery of the electronic component 40 in a surrounding structure, so that the electronic component 40 can be within a protection range of the moisture-proof structure 50. In other words, the electronic component 40 is located inside the moisture-proof structure 50, and can have good moisture-proof performance due to protection of the moisture-proof structure 50. This helps better ensure electrical performance of the electronic component 40. In addition, the surrounding structure may maximize a feature of blocking external moisture in various directions, and maximizes a role of moisture-proof protection. In addition, because the moisture-proof structure 50 is further connected between the first circuit layer 21 and the second circuit layer 22, a height of the moisture-proof structure 50 can completely occupy a height interval between the first circuit layer 21 and the second circuit layer 22, that is, the height of the moisture-proof structure 50 can completely adapt to the height interval of the package body 10, to implement a tight blocking function, and minimize a possibility that the external moisture may pass through the moisture-proof structure 50 and further penetrate into the package body 10.

In other words, the moisture-proof structure 50 is disposed, so that the inside of the moisture-proof structure 50 is defined as an area in which moisture cannot enter, and even if the moisture converges from the outside of the moisture-proof structure 50 to a position of the moisture-proof structure 50, the moisture cannot pass through the moisture-proof structure 50 to enter the defined area protected by the moisture-proof structure 50 due to a moisture-proof feature of the moisture-proof structure 50. This can effectively prevent the external moisture from entering the package substrate 100 from a side edge of the package substrate 100, and prevent a failure of the package substrate 100 due to moisture absorption, and the package substrate 100 has good moisture-proof performance. In addition, the package substrate 100 can have a good environment adaptability as a whole, and can cope with complex and changeable environment changes, so that even in a damp and hot external environment, the package substrate 100 can have good moisture-proof performance, to effectively isolate external moisture, dust, and the like, so as to have high reliability and high practicability.

Because the moisture-proof structure 50 needs to be disposed in the package body 10 and surrounds the electronic component 40, positions for disposing the moisture-proof structure 50 may be diversified. The following describes possibilities of the position of the moisture-proof structure 50 with reference to accompanying drawings.

In a possible implementation, the moisture-proof structure 50 is embedded in the package body 10. It should be understood that, that the moisture-proof structure 50 is embedded in the package body 10 may be understood as that the moisture-proof structure 50 is completely disposed inside the package body 10. That is, the electronic component 40 is inside the moisture-proof structure 50, and a circle of the package material of the package body 10 is still disposed outside the moisture-proof structure 50. That is, the moisture-proof structure 50 is still at a specific distance from the peripheral side surface 103 of the package body 10. For example, the moisture-proof structure 50 may be in an embedded form shown in FIG. 2.

In this way, the moisture-proof structure 50 is completely disposed inside the package body 10, so that even if moisture aggregates from the package body 10 disposed outside the moisture-proof structure 50 to the position of the moisture-proof structure 50, the moisture cannot pass through the moisture-proof structure 50 to enter the small gap between the package body 10 and the pin of the electronic component 40 due to the moisture-proof feature of the moisture-proof structure 50. This can effectively prevent a failure of the package substrate 100 due to moisture absorption, and the package substrate 100 has good moisture-proof performance.

In another possible implementation, a part of the moisture-proof structure 50 is exposed outside a side portion of the package body 10. The side portion may be understood as a peripheral side portion of the package body 10, that is, an edge area that is of the package body 10 and that sequentially surrounds four sides.

For example, as shown in FIG. 3, an outer surface of the moisture-proof structure 50 may be exactly exposed, to form the peripheral side surface 103 of the package body 10. Alternatively, a part of the moisture-proof structure 50 may be disposed inside the package body 10, and the other part may be disposed outside the package body 10.

Therefore, on one hand, the moisture-proof structure 50 can hermetically block moisture of an external environment outside the package body 10, and further prevent the moisture of the external environment from entering the package body 10. This helps ensure electrical performance of the package substrate 100. On the other hand, in a production process of the package body 10, a plurality of package bodies 10 may be arranged in an array manner, and two adjacent package bodies 10 may share one moisture-proof structure 50. Therefore, in a subsequent process, the moisture-proof structure 50 of each package body 10 may be partially exposed outside the side portion of the package body 10. This helps save materials and reduce production management costs while ensuring moisture-proof performance, and helps improve production efficiency of the package substrate 100.

In still another possible implementation, the moisture-proof structure 50 is connected to the peripheral side surface 103 of the package body 10, and is in a structure form in which the moisture-proof structure 50 is completely disposed outside the package body 10. For example, the moisture-proof structure 50 may be in an exposed form shown in FIG. 4.

Therefore, the moisture-proof structure 50 can hermetically block moisture of an external environment outside the package body 10, and further prevent the moisture of the external environment from entering the package body 10. This helps ensure electrical performance of the package substrate 100.

It should be noted that the position of the moisture-proof structure 50 may not be limited to the foregoing described possibilities, provided that the moisture-proof structure 50 can be connected between the first circuit layer 21 and the second circuit layer 22 and surround the electronic component 40. This is not strictly limited in this embodiment of this application.

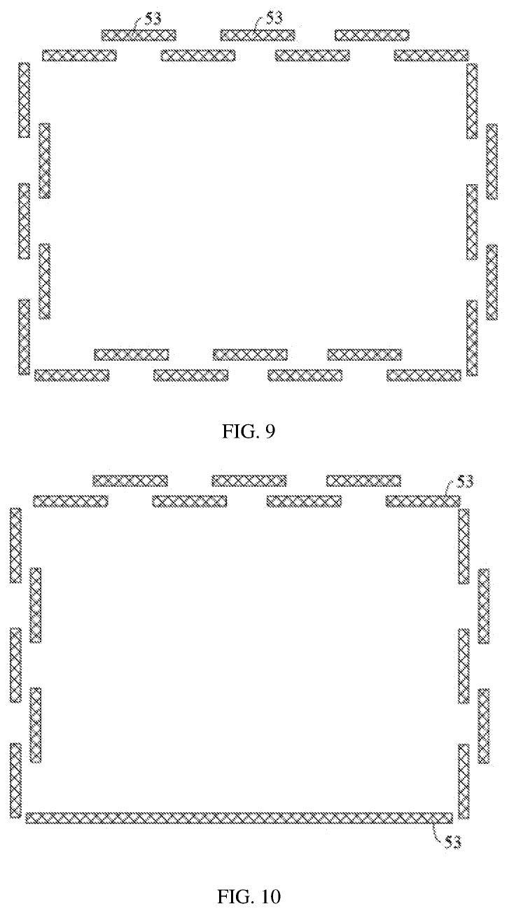

The foregoing describes the possibilities of the position of the moisture-proof structure 50. The following describes possibilities of a structure of the moisture-proof structure 50 with reference to FIG. 8 to FIG. 12.

In a possible implementation, the moisture-proof structure 50 is a continuously-extending closed ring structure.

For example, the moisture-proof structure 50 may be arranged in a four-side closed form shown in FIG. 8. A cross section shown in FIG. 8 is a cross section cut in a direction parallel to the package substrate 100.

In this way, the moisture-proof structure 50 can form a continuous surrounding architecture, and the continuous surrounding architecture can maximize sealing performance of the moisture-proof structure 50, so that external moisture is hermetically blocked outside the continuous surrounding architecture. This helps ensure overall electrical performance of the package substrate 100.

In another possible implementation, the moisture-proof structure 50 includes a plurality of moisture-proof substructures 53, the plurality of moisture-proof substructures 53 are distributed in a staggered manner, and two adjacent moisture-proof substructures 53 at least partially overlap. That is, the plurality of moisture-proof substructures 53 are distributed in the staggered manner inside the peripheral side portion.

For example, the plurality of moisture-proof substructures 53 may be arranged in a four-side staggered form shown in FIG. 9. A cross section shown in FIG. 9 is a cross section cut in a direction parallel to the package substrate 100. It should be understood that, that two adjacent moisture-proof substructures 53 located on a same side at least partially overlap may be understood as that, on a reference surface parallel to the two adjacent moisture-proof substructures 53, orthographic projection that is of one moisture-proof substructure 53 and that is on the reference surface at least partially falls within a range of orthographic projection that is of the other moisture-proof substructure 53 and that is on the reference surface. That two adjacent moisture-proof substructures 53 at least partially overlap may not only mean that the two adjacent moisture-proof substructures 53 located on a same side at least partially overlap, but also may mean that two adjacent moisture-proof substructures 53 located at a corner at least partially overlap.

In this way, the plurality of moisture-proof substructures 53 can be in a discontinuous surrounding structure, and two adjacent moisture-proof substructures 53 do not have a direct connection relationship, and can be in an arrangement form in which positions are staggered. In addition, the two adjacent moisture-proof substructures 53 at least partially overlap, so that an outer contour surrounded by the plurality of moisture-proof substructures 53 is generally in an annular surrounding form, that is, the plurality of moisture-proof substructures 53 can be in a staggered blocking form. This helps minimize a possibility that external moisture penetrates to cause a failure of the package substrate 100 due to moisture absorption.

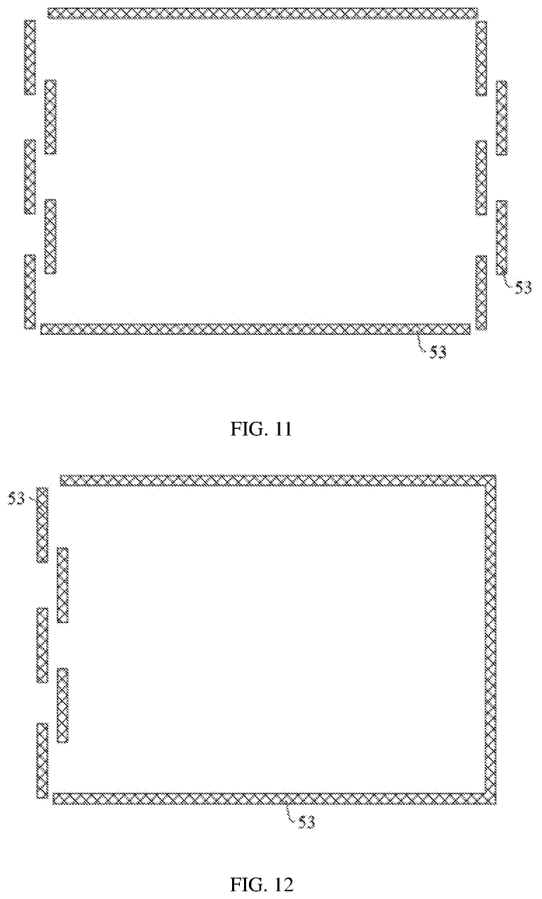

It should be noted that an arrangement form of the plurality of moisture-proof substructures 53 is not limited to the foregoing described possibilities. The arrangement form may alternatively be that one side is continuous and three sides are staggered as shown in FIG. 10, or may be that two sides are continuous and two sides are staggered as shown in FIG. 11, or may be that three sides are continuous and one side is staggered as shown in FIG. 12. Staggered and continuous arrangement and combination forms are not listed herein. However, it should be understood that this embodiment of this application is not limited thereto.

The foregoing describes possibilities of the position and the structure of the moisture-proof structure 50. The following describes in detail structures, positions, and connection forms of the electronic component 40, the first connection column 61, the second connection column 62, the conductive connecting block 70, the moisture-proof structure 50, and the metal layer 80 with reference to a specific structure of the package body 10.

As shown in FIG. 2 to FIG. 7, the package body 10 includes a frame 11 and a package layer 12. The package body 10 is divided into the frame 11 and the package layer 12, so that a structure disposed in the package body 10 can be specifically arranged, to further ensure that the moisture-proof substrate can implement good moisture-proof performance. Details are described below.

The frame 11 includes a first surface 111 and a second surface 112 that are oppositely disposed, and a peripheral side surface 113. The first surface 111, the second surface 112, and the peripheral side surface 113 of the frame 11 jointly form an appearance structure of the frame 11. The frame 11 is further provided with a cavity 114 capable of accommodating the electronic component 40. The cavity 114 is disposed in the frame 11, to implement a packaging form in which the electronic component 40 is embedded in the electronic substrate, so as to improve an arrangement density and integration degree of the package substrate 100.

For example, the frame 11 may be made of an insulated resin material. The resin material may be phenolic resin, epoxy resin, bismaleimide-triazine resin, epoxy acrylate, poly propylene glycol (Poly propylene glycol, PPG), epoxy resin containing glass fibers, epoxy acrylate containing glass fibers, or the like.

It should be noted that the cavity 114 may be concavely disposed on the first surface 111, or may be concavely disposed on the second surface 112, or may pass through the first surface 111 and the second surface 112. There may be one, two, or more cavities 114, provided that one cavity 114 correspondingly accommodates one electronic component 40. This is not strictly limited in this embodiment of this application.

It may be understood that the electronic component 40 may be an active electronic component 40 such as a chip (for example, a CPU chip, a radio frequency drive chip, or another processor chip), a diode, or a transistor, or may be a passive electronic component 40 such as a resistor, an inductor, or a capacitor, or may be a combination of at least two of a chip, a diode, a transistor, a resistor, an inductor, and a capacitor.

The electronic component 40 is accommodated in the cavity 114, and is packaged by using the package layer 12. Specifically, the package layer 12 is filled in the cavity 114, to wrap the electronic component 40 and cover the first surface 111 of the frame 11 and the second surface 112 of the frame 11. In this way, the package layer 12 and the frame 11 can jointly form the package body 10. That is, surfaces of the package layer 12 that are away from the frame 11 respectively form the top surface 101 and the bottom surface 102 of the package body 10, and the package layer 12 and the peripheral side surface 113 of the frame 11 jointly form the peripheral side surface 103 of the package body 10.

For example, the package layer 12 may be made of an insulated resin material. The resin material may be phenolic resin, epoxy resin, bismaleimide-triazine resin, epoxy acrylate, poly propylene glycol (Poly propylene glycol, PPG), epoxy resin containing glass fibers, epoxy acrylate containing glass fibers, or the like.

In a possible implementation, the package layer 12 is made of a material that is the same as the material of the frame 11, and the cavity 114 is filled with the material that is the same as the material of the frame 11, so that there is a good bonding force between the formed package layer 12 and the frame 11, to improve effect of packaging the electronic component 40.

In another possible implementation, the package layer 12 and the frame 11 may be made of different materials.

It may be understood that, because materials for manufacturing the frame 11 and the package layer 12 have specific moisture absorption performance, the frame 11 and the package layer 12 may absorb external moisture, and as a result, an electric-leakage path is formed at the small gap between the package layer 12 and the pin of the electronic component 40. In this way, the moisture-proof structure 50 is disposed and surrounds the electronic component 40, so that the external moisture can be blocked outside the moisture-proof structure 50, and an electric-leakage path is not easily formed at the small gap between the package layer 12 and the pin of the electronic component 40 due to moisture absorption. This minimizes a possibility that the package substrate 100 is faulty due to formation of the electric-leakage path, and fully ensures high reliability and high stability of the package substrate 100 when the package substrate 100 is powered on for use.

This embodiment of this application is described by using an example in which there are two cavities 114 and two electronic components 40, and the two electronic components 40 are respectively a chip and a resistor-capacitor component (a resistor component or a capacitor component). However, it should be understood that this application is not limited thereto.

Specifically, the chip and the resistor-capacitor component are respectively accommodated in two cavities 114, and are packaged by using the package layer 12 (in FIG. 2 to FIG. 7, the chip is on the left, and the resistor-capacitor component is on the right). The first connection column 61 is sleeved in the package layer 12, and is connected between a pin of the chip and the second circuit layer 22, to connect the chip and the second circuit layer 22. The second connection column 62 is sleeved in the package layer 12, and is connected between a pin of the resistor-capacitor component and the second circuit layer 22, to connect the resistor-capacitor component and the second circuit layer 22.

In other words, the chip may be electrically connected to the second circuit layer 22 by using the first connection column 61, and the resistor-capacitor component may be electrically connected to the second circuit layer 22 by using the second connection column 62. It should be noted that a quantity of first connection columns 61 may be corresponding to a quantity of pins of the chip, and a quantity of second connection columns 62 may be corresponding to a quantity of pins of the resistor-capacitor component. This is not strictly limited in this embodiment of this application.

In this embodiment of this application, the conductive connecting block 70 is located on a periphery of the cavity 114, and is electrically connected between the first circuit layer 21 and the second circuit layer 22. A distance between the conductive connecting block 70 and the peripheral side surface 113 of the frame 11 is greater than a distance between the moisture-proof structure 50 and the frame 11. In other words, the conductive connecting block 70 can connect the first circuit layer 21 and the second circuit layer 22, and the conductive connecting block 70 is within a protection range of the moisture-proof structure 50. That is, the conductive connecting block 70 is located inside the moisture-proof structure 50, and can have good moisture-proof performance due to the protection of the moisture-proof structure 50. This helps better ensure electrical performance of the conductive connecting block 70.

It may be understood that, the electronic component 40 (the chip or the resistor-capacitor component) can be electrically connected to the second circuit layer 22, and the conductive connecting block 70 can form an electrical connection relationship between the first circuit layer 21 and the second circuit layer 22, so that the electronic component 40 can implement double-sided interconnection by using the conductive connecting block 70.

In this way, the conductive connecting block 70 is disposed, so that double-sided interconnection of the electronic component 40 can be implemented. This helps shorten a cabling distance and maximize a short-distance transmission path, can effectively implement higher power with a smaller area or volume, and can improve an overall power density, arrangement density, and integration degree of the package substrate 100.

It may be understood that, the conductive connecting block 70 is not only electrically connected between the first circuit layer 21 and the second circuit layer 22, but also physically connected between the first circuit layer 21 and the second circuit layer 22. In other words, the conductive connecting block 70 is located in the frame 11 and the package layer 12.

Specifically, the conductive connecting block 70 includes a first part 71 and a second part 72. The first part 71 is disposed in the frame 11, and the second part 72 is disposed in the package layer 12 and is connected between the first part 71 and the first circuit layer 21 and connected between the first part 71 and the second circuit layer 22. Specifically, one part of the second part 72 is disposed in the package layer 12 located on the first surface 111 and is connected between one end of the first part 71 and the first circuit layer 21, and the other part of the second part 72 is disposed in the package layer 12 located on the second surface 112 and is connected between the other end of the first part 71 and the second circuit layer 22.

In this way, this can fully ensures that a circuit of the package substrate 100 is sleeved in the frame 11 and the package layer 12, so that the first circuit layer 21 and the second circuit layer 22 can be reliably electrically connected by using a short cabling distance.

For example, the first part 71 and the second part 72 may be manufactured by using different manufacturing processes. For example, the first part 71 may be manufactured by using an addition electroplating process, and the second part 72 may be manufactured by using a microvia filling electroplating process.

It should be noted that a position of the conductive connecting block 70 may be designed based on an actual case, provided that the conductive connecting block 70 is located at the periphery of the cavity 114, can connect the first circuit layer 21 and the second circuit layer 22, and is located inside the moisture-proof structure 50. This is not strictly limited in this embodiment of this application.

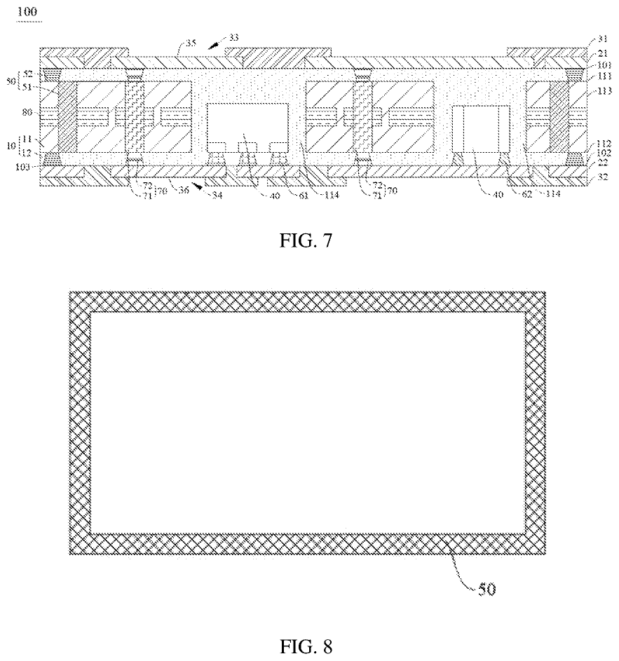

As shown in FIG. 5, FIG. 6, and FIG. 7, the moisture-proof structure 50 may further include a frame baffle wall 51 and a package baffle wall 52, and the frame baffle wall 51 is disposed in the frame 11, and the package baffle wall 52 is disposed in the package layer 12. In other words, the frame baffle wall 51 and the package baffle wall 52 jointly form the moisture-proof structure 50, to prevent moisture of the external environment from entering the package body 10.

It may be understood that the frame baffle wall 51 and the package baffle wall 52 jointly form the moisture-proof structure 50. Because the moisture-proof structure 50 may have only a moisture-proof function but does not have a function of electrically connecting the first circuit layer 21 and the second circuit layer 22, specific positions of the frame baffle wall 51 and the package baffle wall 52 may be diversified. This disposition can further increase a degree of freedom of manufacturing the moisture-proof structure 50, and help reduce a difficulty of manufacturing the package substrate 100.

In a possible implementation, the package baffle wall 52 is connected between the frame baffle wall 51 and the first circuit layer 21 and connected between the frame baffle wall 51 and the second circuit layer 22, and orthographic projection that is of the package baffle wall 52 and that is on the first surface 111 at least partially falls within a range of orthographic projection that is of the frame baffle wall 51 and that is on the first surface 111. That is, at least a part of the package baffle wall 52 overlaps the frame baffle wall 51. One part of the package baffle wall 52 is disposed in the package layer 12 located on the first surface 111 and is connected between one end of the frame 11 and the first circuit layer 21, and the other part of the package baffle wall 52 is disposed in the package layer 12 located on the second surface 112 and is connected between the other end of the frame 11 and the second circuit layer 22. For example, the frame baffle wall 51 and the package baffle wall 52 may be in a structure form shown in FIG. 5.

It should be understood that, that the orthographic projection that is of the package baffle wall 52 and that is on the first surface 111 at least partially falls within the range of the orthographic projection that is of the frame baffle wall 51 and that is on the first surface 111 may be: the orthographic projection that is of the package baffle wall 52 and that is on the first surface 111 partially falls within the range of the orthographic projection that is of the frame baffle wall 51 and that is on the first surface 111, or the orthographic projection that is of the package baffle wall 52 and that is on the first surface 111 completely falls within the range of the orthographic projection that is of the frame baffle wall 51 and that is on the first surface 111. The design can be performed based on an actual case. This is not strictly designed.

In another possible implementation, the package baffle wall 52 is connected between the first surface 111 and the first circuit layer 21 and connected between the second surface 112 and the second circuit layer 22, and the package baffle wall 52 and the frame baffle wall 51 are disposed in a staggered manner. In other words, orthographic projection that is of the package baffle wall 52 and that is on the first surface 111 does not overlap orthographic projection that is of the frame baffle wall 51 and that is on the first surface 111. One part of the package baffle wall 52 is disposed in the package layer 12 located on the first surface 111 and is connected between one end of the frame 11 and the first circuit layer 21, and the other part of the package baffle wall 52 is disposed in the package layer 12 located on the second surface 112 and is connected between the other end of the frame 11 and the second circuit layer 22. For example, the frame baffle wall 51 and the package baffle wall 52 may be in a structure form shown in FIG. 6.

In still another possible implementation, the package baffle wall 52 is connected between the first surface 111 and the first circuit layer 21 and connected between the second surface 112 and the second circuit layer 22, and the package baffle wall 52 is adjacent to the frame baffle wall 51. That is, a relationship between the package baffle wall 52 and the frame baffle wall 51 is a critically contact relationship. One part of the package baffle wall 52 is disposed in the package layer 12 located on the first surface 111 and is connected between one end of the frame 11 and the first circuit layer 21, and the other part of the package baffle wall 52 is disposed in the package layer 12 located on the second surface 112 and is connected between the other end of the frame 11 and the second circuit layer 22. For example, the frame baffle wall 51 and the package baffle wall 52 may be in a structure form shown in FIG. 7.

It should be noted that, for possibilities of the position and the arrangement form of the package baffle wall 52 and the frame baffle wall 51, refer to the possibilities of the position and arrangement form of the moisture-proof structure 50 described above. For example, the frame baffle wall 51 may be embedded inside the frame 11, or may be exposed outside a side portion of the frame 11, and the frame baffle wall 51 may be in a continuous ring structure, or may be in a discontinuous surrounding structure. The frame baffle wall 51 may be embedded inside the package layer 12, or may be exposed outside a side portion of the frame 11. The frame baffle wall 51 may be in a continuous ring structure, or may be in a discontinuous surrounding structure. Arrangement and combination forms of the two may be diversified, and details are not described herein again.

Therefore, on one hand, it can be ensured that the moisture-proof structure 50 can be hermetically disposed between the first circuit layer 21 and the second circuit layer 22, to minimize a possibility of a problem that moisture outside the package substrate 100 penetrates from a loose connection position because the moisture-proof structure 50 is not hermetically connected to the first circuit layer 21 and the second circuit layer 22, resulting in a failure of the package substrate 100 due to moisture absorption. On the other hand, because the moisture-proof structure 50 is disposed on each side of the side portion of the package body 10, moisture from various directions can be effectively blocked, to further improve moisture-proof performance of the package substrate 100.

It may be understood that the package baffle wall 52 and the frame baffle wall 51 may be made of a same metal material, or the package baffle wall 52 and the frame baffle wall 51 may be made of different metal materials. The package baffle wall 52 and the frame baffle wall 51 made of metal can further improve mechanical strength of the package body 10. This helps ensure that the package substrate 100 does not easily deform when the package substrate 100 is subject to an external force.

For example, both the package baffle wall 52 and the frame baffle wall 51 may be made of a metal material, for example, copper. The frame baffle wall 51 and the package baffle wall 52 may also be manufactured by using different manufacturing processes. For example, the frame baffle wall 51 may be manufactured by using an addition electroplating process, and the package baffle wall 52 may be manufactured by using a microvia filling electroplating process.

As shown in FIG. 5, the metal layer 80 is embedded in a middle position in a thickness direction of the frame 11, and the metal layer 80 extends along a direction parallel to the package substrate 100. The thickness direction of the frame 11 may be understood as a direction perpendicular to the frame 11, namely, a direction perpendicular to the package body 10, namely, a direction perpendicular to the package substrate 100. It should be understood that the metal layer 80 is not disposed inside the cavity 114.

In this way, one metal layer 80 is added at the middle position in the thickness direction of the frame 11. Due to a structure feature of the metal layer 80, the frame 11 has good heat dissipation performance as a whole, to significantly improve overall heat dissipation performance and stability of the package substrate 100, and mechanical strength of the frame 11 may be increased, so that the frame 11 does not easily deform due to an external force, to improve the mechanical strength of the package substrate 100.

It should be noted that a size that is of the metal layer 80 and that is in the thickness direction of the frame 11 may be designed based on an actual case. Within a range of ensuring overall performance of the frame 11 and processability of the metal layer 80, a larger size that is of the metal layer 80 and that is in the thickness direction of the frame 11 indicates better heat dissipation performance of the frame 11.

In a possible implementation, as shown in FIG. 5, the metal layer 80 intersects with the conductive connecting block 70, and the metal layer 80 is electrically connected to the conductive connecting block 70. For example, the metal layer 80 is perpendicular to the conductive connecting block 70.

It may be understood that the metal layer 80 can be arranged as a circuit layer and provide specific cabling design. In addition, because the metal layer 80 is connected to the conductive connecting block 70 that can implement a double-sided interconnection function, the metal layer 80 may be manufactured as an interconnection circuit according to an actual design requirement, and a signal shield layer between an upper surface and a lower surface (the first surface 111 and the second surface 112) is formed. In this way, the metal layer 80 can improve the heat dissipation performance, improve the mechanical strength, and provide the cabling design, and has diversified performance, high flexibility, and a wide application scope.

It should be noted that, when the metal layer 80 is disposed as the circuit layer, the metal layer 80 may be discontinuously-extending layer structure design, namely, discontinuous layer structure design. The discontinuous structure design can reserve a specific loop for double-sided interconnection, to ensure reliability of double-sided interconnection.

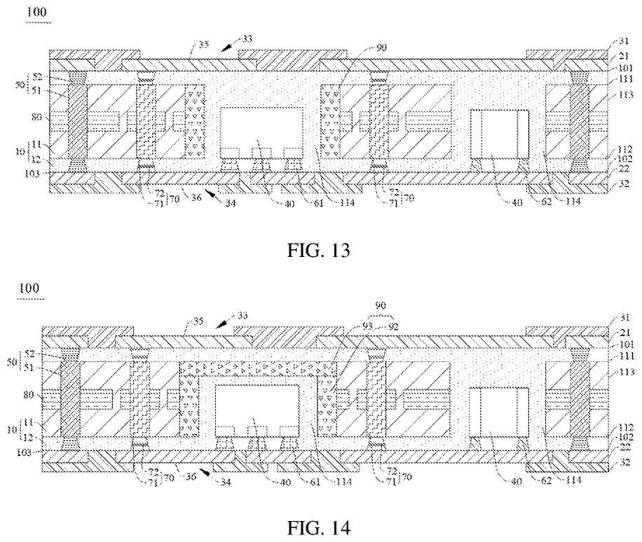

As shown in FIG. 13 and FIG. 14, in this embodiment of this application, the package substrate 100 may further include a signal shielding structure 90 disposed on the frame 11. The signal shielding structure 90 is located between the package baffle wall 52 and the cavity 114 in which the chip is disposed, and surrounds the cavity 114 in which the chip is disposed. A distance between the signal shielding structure 90 and the peripheral side surface 113 of the frame 11 is greater than a distance between the conductive connecting block 70 and the frame 11. In other words, the signal shielding structure 90, the conductive connecting block 70, and the moisture-proof structure 50 are sequentially disposed on a periphery of the cavity 114 in which the chip is disposed. The metal layer 80 may be connected to the signal shielding structure 90, the conductive connecting block 70, and the moisture-proof structure 50.

It may be understood that, the signal shielding structure 90 can be disposed, to avoid signal interference, ensure precision of signal transmission of the chip, and improve stability of the chip during working, so as to minimize a possibility of an exception of the package substrate 100 during working, and fully ensure stability of the package substrate 100 during working.

In a possible implementation, the signal shielding structure 90 is a continuously-extending closed ring structure.

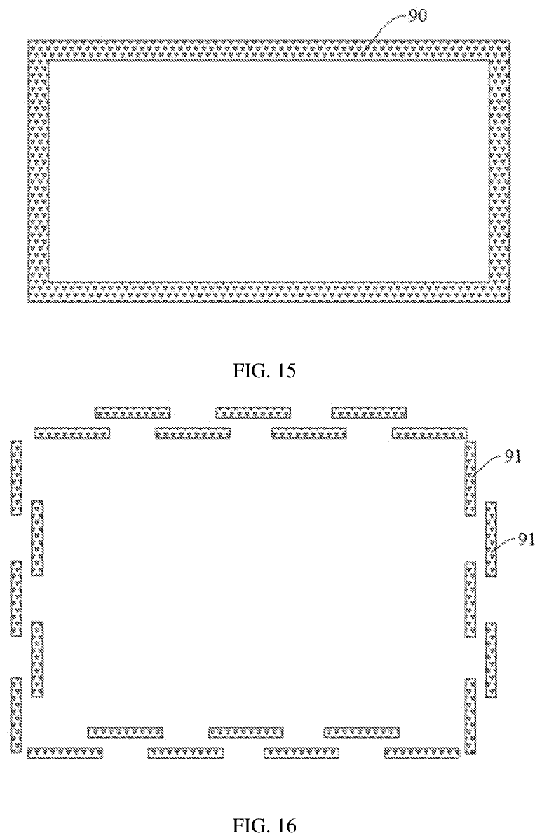

For example, the signal shielding structure 90 may be arranged in a four-side closed form shown in FIG. 15. A cross section shown in FIG. 15 is a cross section cut in a direction parallel to the package substrate 100.

In this way, the signal shielding structure 90 can be disposed around the periphery of the cavity 114 in which the chip is disposed, to form a continuous surrounding architecture. The continuous surrounding architecture can maximize sealing performance of the signal shielding structure 90, and play a good role of shielding signal interference. This helps ensure overall electrical performance of the package substrate 100.

In another possible implementation, the signal shielding structure 90 includes a plurality of signal shielding substructures 91, where the plurality of signal shielding substructures 91 are distributed in the staggered manner inside the peripheral side portion, and two adjacent signal shielding substructures 91 at least partially overlap. That is, the plurality of signal shielding substructures 91 are distributed in the staggered manner inside the peripheral side portion.

For example, the plurality of signal shielding substructures 91 may be arranged in a four-side staggered form shown in FIG. 16. A cross section shown in FIG. 16 is a cross section cut in a direction parallel to the package substrate 100. It should be understood that, that two adjacent signal shielding substructures 91 located on a same side at least partially overlap may be understood as that, on a reference surface parallel to the two adjacent signal shielding substructures 91, orthographic projection that is of one signal shielding substructure 91 and that is on the reference surface at least partially falls within a range of orthographic projection that is of the other signal shielding substructure 91 and that is on the reference surface. That two adjacent signal shielding substructures 91 at least partially overlap may not only mean that the two adjacent signal shielding substructures 91 located on a same side at least partially overlap, but also may mean that two adjacent signal shielding substructures 91 located at a corner at least partially overlap.

In this way, the plurality of signal shielding substructures 91 can be disposed around the periphery of the cavity 114 in which the chip is disposed, to form the discontinuous surrounding structure, and two adjacent signal shielding substructures 91 do not have a direct connection relationship, and can be in an arrangement form in which positions are staggered. In addition, the two adjacent signal shielding substructures 91 at least partially overlap, so that an outer contour surrounded by the plurality of signal shielding substructures 91 is generally in an annular surrounding form, that is, the plurality of signal shielding substructures 91 can be in a staggered blocking form. This helps minimize a possibility that external moisture penetrates to cause a failure of the package substrate 100 due to moisture absorption.

It should be noted that a structure form of the signal shielding structure 90 is not limited to the foregoing described possibilities. The structure form may alternatively be that one side is continuous and three sides are staggered, may be that two sides are continuous and two sides are staggered, or may be that three sides are continuous and one side is staggered. Staggered and continuous arrangement and combination forms are not listed herein. However, it should be understood that this embodiment of this application is not limited thereto.

In still another possible implementation, as shown in FIG. 14, the signal shielding structure 90 includes a shielding baffle wall 92 and a shielding top cover 93. The shielding baffle wall 92 is disposed around a periphery of the cavity 114 in which the chip is disposed, and at least a part of the shielding top cover 93 is located in the cavity 114 in which the chip is disposed, and is connected to one end of the shielding baffle wall 92. It should be understood that the shielding baffle wall 92 may be in a continuously-extending closed ring structure, or may be in a staggered discontinuous surrounding form in the foregoing implementation.

In this way, the signal shielding structure 90 may form a form similar to a lidless box-shaped form. This helps further ensure signal shielding performance of the signal shielding structure 90.

It should be noted that a structure form of the signal shielding structure 90 is not limited to the foregoing described possibilities, and may be a rectangular hexahedron that is embedded in the frame 11 and that wraps the cavity 114 in which the chip is disposed. A hole for the first connection column 61 to pass through is provided only on a surface close to the second circuit layer 22. This is not specifically limited in this embodiment of this application.

Embodiments of this application are described in detail above. The principle and implementation of this application are described herein by using specific examples. The descriptions about embodiments of this application are merely provided, to help understand the method and core ideas of this application. In addition, a person of ordinary skill in the art can make variations and modifications to this application in terms of the specific implementations and application scopes according to the ideas of this application. Therefore, the content of specification shall not be construed as a limit to this application.

What is claimed is:

1. A package substrate, comprising:
a package body, wherein the package body comprises a top surface and a bottom surface that are oppositely disposed;
a first circuit layer and a second circuit layer, wherein the first circuit layer is disposed on the top surface of the package body, and the second circuit layer is disposed on the bottom surface of the package body;
an electronic component, wherein the electronic component is packaged inside the package body; and
a moisture-proof structure, wherein the moisture-proof structure is disposed on the package body and is connected between the first circuit layer and the second circuit layer, and the moisture-proof structure surrounds the electronic component.

2. The package substrate according to claim 1, wherein the moisture-proof structure is a continuously-extending closed ring structure; or
the moisture-proof structure comprises a plurality of moisture-proof substructures, the plurality of moisture-proof substructures are distributed in a staggered manner, and two adjacent moisture-proof substructures at least partially overlap.

3. The package substrate according to claim 1, wherein the moisture-proof structure is embedded in the package body; or
at least a part of the moisture-proof structure is exposed on a side portion of the package body.

4. The package substrate according to claim 1, wherein the package body comprises a frame and a package layer, the frame is provided with a cavity, the electronic component is accommodated in the cavity, the frame further comprises a first surface and a second surface that are oppositely disposed, the package layer is filled in the cavity, to wrap the electronic component and cover the first surface and the second surface, and surfaces of the package layer that are away from the frame form the top surface and the bottom surface;
the moisture-proof structure comprises a frame baffle wall and a package baffle wall, the frame baffle wall is disposed on the frame, and the package baffle wall is disposed on the package layer; and
the package baffle wall is connected between the frame baffle wall and the first circuit layer and connected between the frame baffle wall and the second circuit layer, and orthographic projection that is of the package baffle wall and that is on the first surface at least partially falls within a range of orthographic projection that is of the frame baffle wall and that is on the first surface; or
the package baffle wall is connected between the first surface and the first circuit layer and connected between the second surface and the second circuit layer, and the package baffle wall and the frame baffle are disposed in a staggered manner; or
the package baffle wall is connected between the first surface and the first circuit layer and connected between the second surface and the second circuit layer, and the package baffle wall is adjacent to the frame baffle wall.

5. The package substrate according to claim 4, wherein the electronic component is a chip, the package substrate further comprises a signal shielding structure disposed on the frame, and the signal shielding structure is located between the package baffle wall and the cavity and surrounds the cavity.

6. The package substrate according to claim 5, wherein the signal shielding structure is a continuously-extending closed ring structure; or
the signal shielding structure comprises a shielding baffle wall and a shielding top cover, the shielding baffle wall is disposed around a periphery of the cavity, and at least a part of the shielding top cover is located in the cavity and is connected to one end of the shielding baffle wall.

7. The package substrate according to claim 4, wherein the package substrate further comprises a conductive connecting block disposed on the frame, and the frame further comprises a peripheral side surface connecting the first surface and the second surface; and
the conductive connecting block is located outside the cavity, and is electrically connected between the first circuit layer and the second circuit layer; and a distance between the conductive connecting block and the peripheral side surface of the frame is greater than a distance between the moisture-proof structure and the frame.

8. The package substrate according to claim 1, wherein the package body further comprises a metal layer, the metal layer is embedded in a middle position in a thickness direction of the frame, and the metal layer extends along a direction parallel to the package substrate.

9. The package substrate according to claim 8, wherein the metal layer intersects with the conductive connecting block, and the metal layer is electrically connected to the conductive connecting block.

10. The package substrate according to claim 1, wherein the package substrate further comprises a first solder mask layer and a second solder mask layer;
the first solder mask layer is disposed on a surface that is of the first circuit layer and that is away from the package body, and covers a part of the top surface that is of the package body and that is not covered by the first circuit layer, the first solder mask layer is provided with a first opening, and the first opening exposes a part of the first circuit layer, so that the exposed part of the first circuit layer forms a first pad of the package substrate; and
the second solder mask layer is disposed on a surface that is of the second circuit layer and that is away from the package body, and covers a part of the bottom surface that is of the package body and that is not covered by the second circuit layer, the second solder mask layer is provided with a second opening, and the second opening exposes a part of the second circuit layer, so that the exposed part of the second circuit layer forms a second pad of the package substrate.

11. A communication device, wherein the communication device comprises a circuit board and the package substrate according to claim 1, and the package substrate is disposed on the circuit board.
